(19) United States
(12) Patent Application Publication
(10) Pub. No.: US 2024/0401957 A1
(43) Pub. Date: Dec. 5, 2024

(54) Wayfinding and Guidance to Assets, Devices and Sensors in Buildings

(71) Applicant: Siemens Schweiz AG, Zürich (CH)

(72) Inventors: Oliver Hasler, Zug (CH); Sandro Blatter, St. Gallen (CH)

(73) Assignee: Siemens Schweiz AG, Zürich (CH)

(21) Appl. No.: 18/699,810

(22) PCT Filed: Jul. 21, 2022
(86) PCT No.: PCT/EP2022/070441

§ 371 Date: Apr. 9, 2024

(30) Foreign Application Priority Data
Oct. 11, 2021 (EP) 21201909.5

(51) Int. Cl. G01C 21/20; G01C 22/00; G06F 30/13; H04W 4/029; H04W 4/33

(52) U.S. Cl. CPC G01C 21/206; G01C 22/006; G06F 30/13; H04W 4/029; H04W 4/33

(57) ABSTRACT

The teachings of the present disclosure relate to navigating a user to a device located in a building. An example embodiment includes: a mobile communication device (smartphone, tablet computer) to select the device to navigate to by user input, wherein the mobile communication device is connected to an object model (OM) representing the devices located in the building; and a server comprising access to a memory where the object model (OM) is stored, wherein the server is configured to determine a route from the position of the user to the device to navigate to based on information provided by the object model (OM). The route to the device to navigate to is displayed and synchronized on the display of the mobile communication device.

### CROSS-REFERENCE TO RELATED APPLICATIONS

This application is a U.S. National Stage Application of International Application No. PCT/EP2022/070441 filed Jul. 21, 2022, which designates the United States of America, and claims priority to EP application Ser. No. 21/201,909.5 filed Ocotber 11, 2021, the contents of which are hereby incorporated by reference in their entirety.

### TECHNICAL FIELD

The present disclosure relates to building management systems or building automation systems comprising a plurality of building devices, e.g. controllers. Some embodiments of the teachings of the present disclosure include methods and/or systems for navigating a user to a device located or installed in a building.

### BACKGROUND

To find assets or devices in a building that are hidden behind walls or are otherwise hidden from sight (built into the concrete structure of the building; lowered ceilings etc.) is sometimes onerous for technicians. Technicians usually consult various 2D drawings of questionable age and data quality. Afterwards they try to find the assets or devices via trial and error.

### SUMMARY

The teachings of the present disclosure provide efficient methods and/or arrangements for navigating a user to a device or asset located or installed in a building. As an example, some embodiments include a method for navigating a user to a device located in a building, the method comprising: providing a mobile communication device (e.g. smartphone, tablet computer) configured to select the device to navigate to by user input, wherein the mobile communication device is connected to an object model (e.g. BIM) representing the devices located in the building; determining a route from the position of the user to the device to navigate to based on information provided by the object model and/or an Indoor-Positioning-System; displaying the route to the device to navigate to on the display of the mobile communication device; tracking the progress of the walking along the determined route by recording measured values of sensors (e.g. step counter or gyrometric sensor) integrated in the mobile communication device; keeping the user on track and synchronized with the determined route by scanning landmark codes (e.g. QR code) attached in the building and/or by radio and/or audio and/or camera means of the mobile communication device; and synchronizing a pointer representing the user within the object model to the exact same position in the object model the user is currently in the building; wherein when the user arrives at the device to navigate to, the average step distance of the user, the number of steps the user needed to arrive at the device to navigate to, and the time the user needed to arrive at the device to navigate to is stored in a suitable navigation data memory; wherein based on the data stored in the navigation data memory future routes for navigating a user to a device located in the building are determined.

As another example, some embodiments include an arrangement for navigating a user to a device located in a building, comprising: a mobile communication device (smartphone, tablet computer) configured to select the device to navigate to by user input, wherein the mobile communication device is connected to an object model (e.g. BIM) representing the devices located in the building; and a server (e.g. cloud server) comprising access to a memory where the object model is stored, wherein the server is configured to determine a route from the position of the user to the device to navigate to based on information provided by the object model; wherein the route to the device to navigate to is displayed on the display of the mobile communication device; wherein the mobile communication device is configured to track the progress of the walking along the determined route by recording measured values of sensors (e.g. step counter or gyrometric sensor) integrated in the mobile communication device; wherein the mobile communication device s further configured to keep the user on track and synchronized with the determined route by scanning landmark codes (e.g. QR code) attached in the building and/or by radio and/or audio and/or camera means of the mobile communication device; wherein the server is configured to synchronize a pointer representing the user within the object model to the exact same position in the object model the user is currently in the building; wherein when the user arrives at the device to navigate to, the average step distance of the user, the number of steps the user needed to arrive at the device to navigate to, and the time the user needed to arrive at the device to navigate to is stored by the server or by the mobile communication device in a suitable navigation data memory; wherein the server is further configured based on the data stored in the navigation data memory to determine future routes for navigating a user to a device located in the building.

As other examples, some embodiments include a computer program product and a computer-readable storage medium comprising instructions which, when the program is executed by a computer, cause the computer to carry out one or more of the methods for navigating a user to a device located in a building as described herein.

### BRIEF DESCRIPTION OF THE DRAWINGS

The above-mentioned and other concepts of the present disclosure are addressed with reference to the drawings of the example embodiments of the teachings of the present disclosure. The shown embodiments are intended to illustrate, but not to limit the scope of the disclosure. The drawings contain the following figures, in which like numbers refer to like parts throughout the description and drawings and wherein:

FIG. 1 illustrates a flowchart of an example method for navigating a user to a device located in a building incorporating teachings of the present disclosure;

FIG. 2 illustrates an example arrangement for navigating a user to a device located in a building incorporating teachings of the present disclosure;

FIG. 3 illustrates an image of an example display to navigate a user to a device located in a building incorporating teachings of the present disclosure; and

FIG. 4 illustrates an image of another example display to navigate a user to a device located in a building incorporating teachings of the present disclosure.

### DETAILED DESCRIPTION

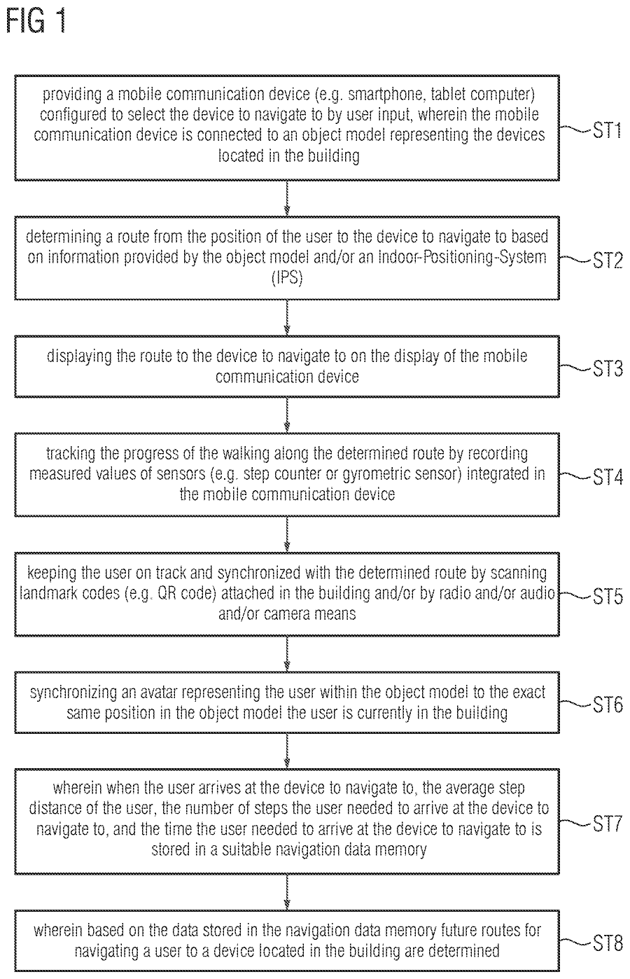

FIG. 1 illustrates a flowchart of an example method for navigating a user to a device located in a building. The method shown comprises: (ST1) providing a mobile communication device (e.g. smartphone, tablet computer) configured to select the device to navigate to by user input, wherein the mobile communication device is connected to an object model (OM) representing the devices located in the building; (ST2) determining a route from the position of the user to the device to navigate to based on information provided by the object model (OM) and/or an Indoor-Positioning-System (IPS); (ST3) displaying the route to the device to navigate to on the display of the mobile communication device; (ST4) tracking the progress of the walking along the determined route by recording measured values of sensors (e.g. step counter or gyrometric sensor) integrated in the mobile communication device; (ST5) keeping the user on track and synchronized with the determined route by scanning landmark codes (e.g. QR code) attached in the building and/or by radio and/or audio and/or camera means of the mobile communication device (MG); (ST6) synchronizing a pointer (e.g. a graphical indicator, e.g. an arrow or an point) representing the user within the object model (OM) to the exact same position in the object model (OM) the user is currently in the building; (ST7) wherein when the user arrives at the device to navigate to, the average step distance (ASD) of the user (P), the number of steps (NS) the user (P) needed to arrive at the device (Dev) to navigate to, and the time (T) the user needed to arrive at the device (Dev) to navigate to is stored in a suitable navigation data memory (NDM); (ST8) wherein based on the data stored in the navigation data memory future routes for navigating a user to a device located in the building are determined.

The method can be performed by using commercial off the shelf (COTS) devices which are configured and equipped with suitable HW means and software programs. The mobile communication device can be a smartphone or a tablet computer. Tracking the route may be supported by an Indoor-Positioning-System (IBeacons, WLAN, etc). In some embodiments, scanning of landmark codes is performed by a QR code reader of the mobile communication device. The QR code reader can be installed on the mobile communication device by a suitable App (e.g. by download from an App-Store). For example, IFC notation (industry foundation class) can be used as object model notation. The method can be realized by using a cloud infrastructure, comprising a cloud server with access to the object model. The cloud server comprises means for processing, communicating, and storing.

In some embodiments, the object model can be stored locally on the mobile communication device, partly or completely). The object model can also be stored on the server and streamed and/or mirrored and/or loaded from the server to the mobile communication device.

According to Wikipedia an avatar is a graphical representation of a user or the user's character or persona. It may take either a two-dimensional form as an icon in Internet forums and other online communities or a three-dimensional form, as in games or virtual worlds.

In some embodiments, displaying the route comprises the illustration of the pointer the route. The pointer is a graphical representation of the user on the display of the mobile communication device. The pointer can be for instance, an arrow or a point or an avatar.

In some embodiments, the navigation data memory is part of the object model. In some embodiments, the object model is a building information model (BIM) or a UNITY-based rendered model (e.g. a 3D-model). In some embodiments, the object model is represented in IFC notation.

The method can be realized in an online-mode or in an offline-mode. In the online-mode the mobile communication device may be connected permanently with a server (e.g. cloud server) providing the object model (e.g. BIM Model). In the offline-mode the object model is stored locally on the mobile communication device. In some embodiments, the user can switch between online-mode and offline-mode. In some embodiments, during online-mode an object model stored locally on the mobile communication device can be updated and/or synchronized according to an object model stored in a server (e.g. cloud server). In some embodiments, information regarding the device (e.g. asset to be navigated to) is provided and displayed to a user on the mobile communication device. In some embodiments, the user can retrieve information about the device and/or communicate and/or interact directly with the device (e.g. an IoT device, connected to the Internet). In some embodiments, this interaction is then also stored directly in the asset, sent to a server, and/or first kept locally and later optionally “synchronized”. Furthermore, optimized service technician are able to be routed to the device (asset). In some embodiments, several route variants are provided which can be selected by the user: fastest route to the device (asset) to be navigated to and/or optimal route (taking into account expected on-site complexity as far as service is concerned) and/or whatever-it-takes route.

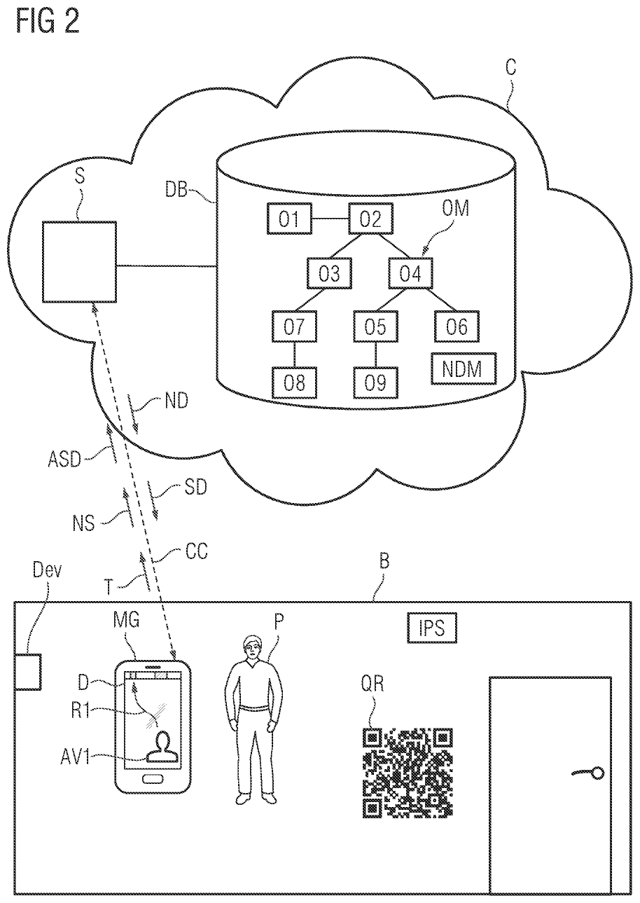

FIG. 2 illustrates an exemplary arrangement for navigating a user P to a device Dev located in a building B. The exemplary arrangement comprises: a mobile communication device MG (e.g. smartphone, tablet computer) configured to select the device Dev to navigate to by user input, wherein the mobile communication device MG is connected to an object model OM representing the devices Dev located in the building B; a server S comprising access to a memory DB where the object model OM is stored, wherein the server S is configured to determine a route R1 from the position of the user P to the device Dev to navigate to based on information provided by the object model OM; wherein the route R1 to the device Dev to navigate to is displayed on the display D of the mobile communication device MG; wherein the mobile communication device MG is configured to track the progress of the walking along the determined route R1 by recording measured values of sensors (e.g. step counter or gyrometric sensor) integrated in the mobile communication device MG; wherein the mobile communication device MG is further configured to keep the user P on track and synchronized with the determined route R1 by scanning landmark codes QR (e.g. QR code, bar code) attached in the building B and/or by radio and/or audio and/or camera means of the mobile communication device MG; wherein the server S is configured to synchronize a pointer AV1-AV3 representing the user P within the object model OM to the exact same position in the object model OM the user P is currently in the building B; wherein when the user P arrives at the device Dev to navigate to, the average step distance of the user P, the number of steps the user needed to arrive at the device Dev to navigate to, and the time the user needed to arrive at the device Dev to navigate to is stored by the server S or by the mobile communication device MG in a suitable navigation data memory NDM; and wherein the server S is further configured based on the data stored in the navigation data memory NDM to determine future routes R1-R3 for navigating a user P to a device Dev located in the building B. The device Dev to navigate to can be a controller installed in the building B. The device Dev to navigate to can also be an asset (e.g. technical equipment or a machine) located in the building B. The mobile communication device MG can be a suitable configured smartphone or tablet computer. The mobile communication device MG comprises suitable sensors (e.g. step counter or gyrometric sensor). The sensors can be integrated in the mobile communication device MG. Sensor functionality can also be installed on the mobile communication device MG by download of an App providing sensor functionality.

In some embodiments, for determining the position of the user P in the building an Indoor-Positioning-System IPS (e.g. IBeacons, BLE, WLAN) is used. The mobile communication device MG is configured to communicate with the Indoor-Positioning-System IPS to determine the position of the mobile communication device MG. The mobile communication device MG is configured to read or scan, and process landmark codes QR (e.g. QR code, bar code) located in the building B. In some embodiments, the mobile communication device MG comprises a suitable QR-Code Reader (e.g. an App).

In some embodiments, the server S, the memory DB, and the navigation data memory NDM are implemented in a cloud infrastructure C. The cloud infrastructure C is providing suitable processing means, storing means, and communication means.

The server S is a suitable computer (e.g. desktop computer, workstation, laptop) comprising suitable processing means (Hardware and Software), storing means (e.g. ROM, RAM, Flash memories), and communication means (e.g. Internet connection).

The memory DB where the object model OM is stored can be suitable database (relational database, In-Memory database, etc.). The object model OM represents the devices and/or assets of the building B in a suitable data model or object model OM. The data model or object model OM is representing and/or mapping the devices Dev and/or assets of the building B in a suitable notation (e.g. IFC notation, Industry Foundation Class). The devices Dev and/or assets of the building B are represented in the data model or object model OM by respective objects O1-O9.

In some embodiments, the data model or object model OM comprises attributes and relationships of the objects O1-O9. In some embodiments, the data model or object model OM is a building information model (BIM model). A BIM model is a building model that can be used by all parties involved in a building project (architects, engineers, fire protection specialists, building authorities, HVAC engineers, facility management specialists) during the design, construction and operation phases of a building. In the BIM model (building model), all relevant building data is digitally captured, combined and networked. The BIM model is thus a virtual model of the building and the trades installed in the building. An appropriately maintained BIM model ensures that the trades installed in the building and their relationships are up to date. In some embodiments, a BIM model is based on the standardized “Industry Foundation Classes” (IFC). In some embodiments, the BIM model includes, among other things, the installation location of the trades located in a building (e.g. HVAC systems for heating, ventilation or cooling).

In the navigation data memory NDM navigation data from and/or for the respective routes R1 are collected and stored. The navigation data memory NDM is storing for instance the following data: the average step distance of the user P, the number of steps the user P needed to arrive at the device Dev to navigate to, and the time the user P needed to arrive at the device Dev to navigate to. These data are used for navigation and synchronization a user on future routes. This can be accomplished by means of artificial intelligence (AI), e.g. neuronal networks, machine learning algorithms, deep learning algorithms. The navigation data memory NDM can be an object and/or a part of the object model OM. The navigation data memory NDM can be a part of the database DB. The navigation data memory NDM can also be implemented in a separate database.

The user P can be for instance, a facility manager, a service or maintenance worker, or a commissioner.

By using suitable communication connections CC (e.g. WLAN, radio, Internet) the mobile communication device MG of the user P communicates with the server S. The mobile communication device MG is providing the following data to the server S: the Average Step Distance ASD, the time T (actual time and/or time consumed since starting point), Number of Steps (since starting point) NS. These data are stored in the navigation data memory NDM for future route navigations. These data are processed by the server S to provide for the current route synchronization data SD and navigation data ND. In some embodiments, navigation data ND are also provided by the Indoor-Positioning-System IPS. In some embodiments, the server S, the Indoor-Positioning-System IPS, and the mobile communication device MG are configured to collaborate to determine and/or provide the respective synchronization data SD and navigation data ND.

The user P that needs to find a device Dev (e.g. a sensor or valve or controller) uses an app or other computer-aided solution to calculate the quickest/safest/most-efficient/etc. way to reach the target Dev. In order to achieve this, the information is being calculated with the help of an accurate object model OM (e.g. 3D BIM model, Building Information Model). Afterwards the tracking can begin. The software/algorithm (invention) utilizes one or multiple sensors within a portable communication device MG (e.g. smartphone, tablet, . . . ), for example a step counter or gyrometric sensor. With that information at hand, the invention tracks the progress along the calculated and chosen route R1. During all that time the user P can visibly track the position of his/her pointer (e.g. avatar AV1) within the app (3D representation) and compare it to the real time and real-life view of his current position.

To keep the user P on track and synchronized with the navigation route R1 inside the object model OM (e.g. BIM model), the methods and systems described herein allow him to scan various QR codes QR or receive information via other means, such as e.g. radio, audio or camera. These codes will synchronize his/her avatar AV1 inside the object model OM (e.g. BIM model) to the exact same position that he is currently in. The systems and methods can also make use of integrated sensors, such as a light-detection-sensor, of a smart device MG, to detect whether the user P has been near to a lamp or a bright light source. This information will be at or near-real-time compared to the object model OM (e.g. BIM model). Inside the object model OM there will be a look up for a corresponding light source and the pointer (e.g. avatar AV1) will be calibrated according to that information. In some embodiments, the person/user P becomes the Avatar AV1 within the object model OM. The Avatar's AV1 position will be determined by the current location of the person/user P using the app. The “playing field”, the Avatar's world, is a representation, a real model of the real building B the person/user P is moving in.

After the arrival of the user P at the target Dev location, the systems and/or methods will calculate the average step distance ASD and time T needed. This information can be used to compute a better approximation of step length and other movement information (stride, slow downs etc.) in future navigation calculations. Henceforth, the tracking of the or a similar generic user P and its corresponding synchronization with the pinter (e.g. avatar AV1) inside the object model OM will be more accurate.

A person P that must look in a building B for a certain device Dev will find that device Dev a lot faster than previous. So, saving precious time for actual fixing the device. Especially when the device Dev is hidden for example in a lower ceiling, the person that need to find a device there, must demount various overhead panels to find the wished device. With the teachings herein there is no need for searching and hoping a device will be there. The person P will be shown the fastest way R1 to it and the navigation will be synchronized with the latest data of the object model OM.

In some embodiments, the mobile communication device MG is configured to illustrate the pointer AV1 (e.g. avatar AV1) on the route R1. The pointer AV1 can be illustrated for instance, in form of an arrow, or as a point, or as an avatar AV1.

In some embodiments, the navigation data memory NDM is part of the object model OM.

In some embodiments, the object model OM is a building information model (BIM) or a UNITY-based rendered model.

In some embodiments, the server S is part of a cloud infrastructure C or implemented in a cloud infrastructure C.

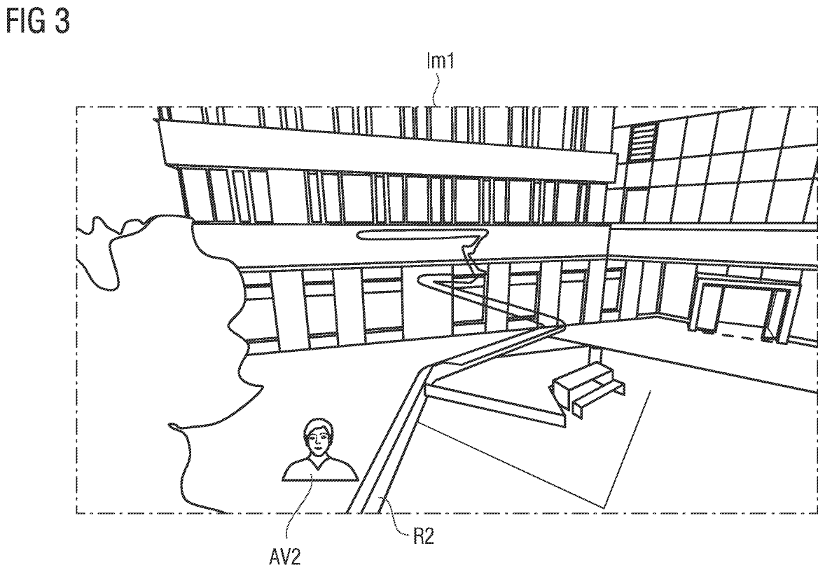

FIG. 3 illustrates an image Im1 of a first example display of a mobile communication device to navigate a user to a device or object located in a building. FIG. 3 shows a fully calculated way (route R2) in a schematic building to the object (e.g. device or asset) to be navigated to, and an avatar AV2 representing the user.

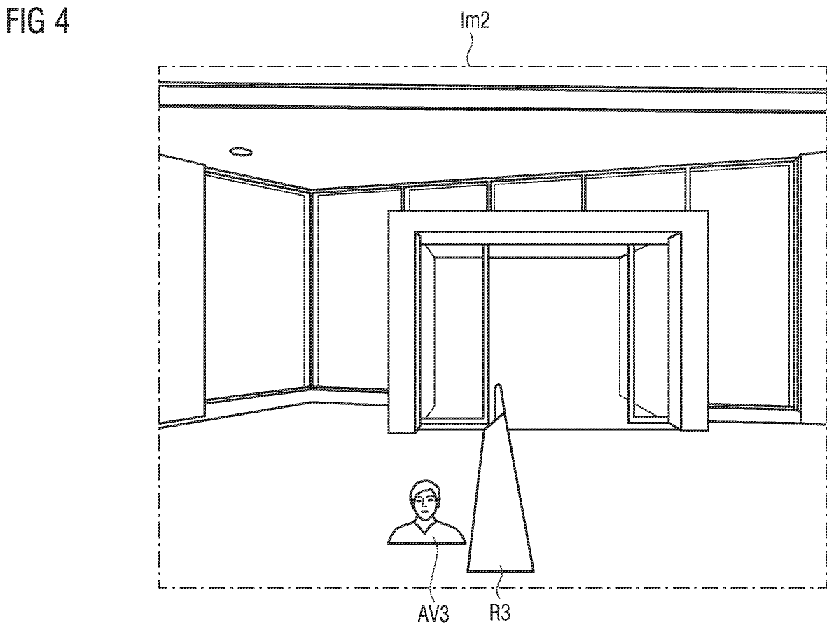

FIG. 4 illustrates an image Im2 of a second example display of a mobile communication device to navigate a user to a device or object located in a building. FIG. 4 shows a view during navigation to the object (e.g. device or asset) to be navigated to on the respective route R3, and an avatar AV3 representing the user.

### REFERENCE SIGNS

OM Object Model
O1-O9 Object
Dev Device
IM1, IM2 Image
D Display
B Building
QR QR Code
R1-R3 Route
AV1-AV3 Avatar
S Server
DB Database
C Cloud
P User
IPS Indoor-Positioning System
CC Communication Connection
MG Mobile Communication Device
T Time
NS Number of Steps
ASD Average Step Distance
ND Navigation Data
SD Synchronization Data
NDM Navigation Data Memory
ST1-ST8 Step

What is claimed is:

1. A method for navigating a user to a selected device located in a building, the method comprising:
receiving a selection from a user through a mobile communication device configured to select the device from a plurality of device to navigate to, wherein the mobile communication device s connected to an object model representing the plurality of devices located in the building;
determining a route from a position of the user to the selected device to navigate to based on information provided by the object model and/or an Indoor-Positioning-System;
displaying the determined route on a display of the mobile communication device;
tracking progress of the user walking along the determined route by recording measured values of sensors integrated in the mobile communication device;
keeping the user on track and synchronized with the determined route by scanning landmark codes attached in the building and/or by radio and/or audio and/or camera means of the mobile communication device;
synchronizing a pointer representing the user within the object model to the position the user is currently in the building;
storing the average step distance of the user, the number of steps the user needed to arrive at the device to navigate to, and the time the user needed to arrive at the device to navigate in a suitable navigation data memory; and
determining future routes based on the data stored in the navigation data memory for navigating a subsequent user.

2. The method according to claim 1, wherein displaying the route comprises illustrating the pointer on the route.

3. The method according claim 1, wherein the navigation data memory is part of the object model.

4. The method according to claim 1, wherein the object model comprises a building information model or a UNITY-based rendered model.

5. An arrangement for navigating a user to a device located in a building, the arrangement comprising:
a mobile communication device to receive user input selecting the device to navigate to, the mobile communication device connected to an object model representing a plurality of devices located in the building;
a server comprising a memory storing the object model, the server configured to determine a route from a position of the user to the selected device based on information provided by the object model;
wherein the mobile communication device includes a display for the route to the selected device;
the mobile communication device tracks the progress of the walking along the determined route by recording measured values of sensors integrated in the mobile communication device;
the mobile communication device keeps the user on track and synchronized with the determined route by scanning landmark codes attached in the building and/or by radio and/or audio and/or camera means of the mobile communication device;
the server synchronizes a pointer representing the user within the object model at the position the user is currently in the building;
when the user arrives at the device, the average step distance of the user, the number of steps the user needed to arrive at the device, and the time the user needed to arrive at the device is stored by the server or by the mobile communication device in a suitable navigation data memory; and
the server, based on the data stored in the navigation data memory, determines future routes for navigating a user to one of the plurality of devices.

6. The arrangement according to claim 5, wherein the mobile communication device illustrates the pointer on the route.

7. The arrangement according claim 5, wherein the navigation data memory is part of the object model.

8. The arrangement according to claim 5, wherein the object model comprises a building information model or a UNITY-based rendered model.

9. The arrangement according to claim 5, wherein the server is part of a cloud infrastructure.

10-11. (canceled)
